(19) United States
(12) Patent Application Publication
(10) Pub. No.: US 2020/0174921 A1
(43) Pub. Date: Jun. 4, 2020

(54) DATA STORAGE DEVICE, OPERATION METHOD THEREOF, AND STORAGE SYSTEM INCLUDING THE SAME

(71) Applicant: SK hynix Inc., Gyeonggi-do (KR)

(72) Inventor: Da Seul LEE, Gyeonggi-do (KR)

(21) Appl. No.: 16/527,466

(22) Filed: Jul. 31, 2019

(30) Foreign Application Priority Data
Dec. 3, 2018 (KR) 10-2018-0153898

(51) Int. Cl. G06F 12/02; G11C 11/22; G06F 11/10; G06F 11/07

(52) U.S. Cl. CPC G06F 12/0253; G06F 12/0246; G06F 11/0793; G06F 11/1092; G11C 11/2273

(57) ABSTRACT

A data storage device includes a storage configured to include a plurality of memory blocks and a controller configured to control data input/output to/from the storage. Wherein the controller comprises a command queue configured to queue a host command transmitted from a host device and a force garbage collection controller configured to control force garbage collection to be performed in preference to the queued host command when a block requiring the force garbage collection is detected from the plurality of memory blocks.

### CROSS-REFERENCES TO RELATED APPLICATION

The present application claims priority under 35 U.S.C. § 119(a) to Korean application number 10-2018-0153898 filed on Dec. 3, 2018, which is incorporated herein by reference in its entirety.

### BACKGROUND

### 1. Technical Field

Various embodiments generally relate to a semiconductor integrated apparatus, and more particularly, to a data storage device, an operation method thereof, and a storage system including the same.

### 2. Related Art

A storage device is electrically connected to a host device and performs a data input/output operation at a request of the host. The storage device may use various storage media in order to store data.

A storage medium using a flash memory has an advantage such as large capacity, nonvolatility, low unit cost, low power consumption, and a high speed data processing speed.

However, in the flash memory, when a read operation for a specific block is repeated, since a threshold voltage level of memory cells included in the block is transitioned, stored data may be damaged. This is called a read disturbance phenomenon and causes an increase in a read error rate.

In order to substantially prevent the read disturbance phenomenon, data of a block read more than a predetermined number of times may be moved to another block.

When a block, whose data has not been moved at an appropriate time, is read more than a read limit, the block is no longer available.

### SUMMARY

In an embodiment, a data storage device may include: a storage configured to include a plurality of memory blocks; and a controller configured to control data input/output to/from the storage, wherein the controller comprises: a command queue configured to queue a host command transmitted from a host device; and a force garbage collection controller configured to control force garbage collection to be performed in preference to the queued host command when a block requiring the force garbage collection is detected from the plurality of memory blocks.

In an embodiment, an operation method of a data storage device including a storage configured to include a plurality of memory blocks and a controller having a command queue configured to queue a host command transmitted from a host device and a force garbage collection controller and configured to control data input/output to/from the storage by scheduling the queued host command, the operation method comprising: monitoring by the force garbage collection controller, to determine whether a block requiring force garbage collection is detected from the plurality of memory blocks; and performing by the force garbage collection controller, the force garbage collection in preference to the queued host command when the block requiring the force garbage collection is detected.

In an embodiment, a storage system may include: a host device; a storage configured to include a plurality of memory blocks; and a controller configured to control data input/output to/from the storage, wherein the controller comprises: a command queue configured to queue a host command transmitted from the host device; and a force garbage collection controller configured to control force garbage collection to be performed in preference to the queued host command when a block requiring the force garbage collection is detected from the plurality of memory blocks.

In an embodiment, a memory system may include: a memory device including memory blocks; and a controller configured to: control the memory device to perform one or more operations in response to one or more queued commands, respectively; and control the memory device to perform a force garbage collection operation to a target block among the memory blocks prior to processing the queued commands upon detection of the target block.

### BRIEF DESCRIPTION OF THE DRAWINGS

FIG. 1 is a configuration diagram of a data storage device in accordance with an embodiment.

FIG. 2 is a configuration diagram of a controller in accordance with an embodiment.

FIG. 3 is a configuration diagram of a Force Garbage Collection (FGC) controller in accordance with an embodiment.

FIG. 4 is a flowchart describing an operation method for a data storage device in accordance with an embodiment.

FIG. 5 is a configuration diagram of a storage in accordance with an embodiment.

FIG. 6 is a diagram describing a command processing concept in accordance with an embodiment.

FIG. 7 is a diagram illustrating a data storage system in accordance with an embodiment.

FIG. 8 and FIG. 9 are diagrams illustrating a data processing system in accordance with an embodiment.

FIG. 10 is a diagram illustrating a network system including a data storage device in accordance with an embodiment.

FIG. 11 is a block diagram illustrating a nonvolatile memory device included in a data storage device in accordance with an embodiment.

### DETAILED DESCRIPTION

Hereinafter, a data storage device, an operation method thereof, and a storage system including the same will be described below with reference to the accompanying drawings through various examples of embodiments.

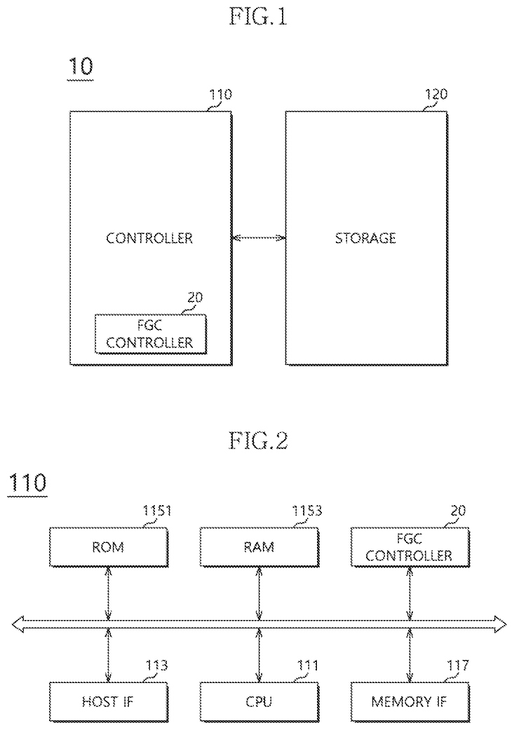

FIG. 1 is a configuration diagram of a data storage device in accordance with an embodiment.

Referring to FIG. 1, a data storage device 10 in accordance with an embodiment may include a controller 110 and a storage 120.

The controller 110 may control the storage 120 in response to a request of a host device. For example, the controller 110 may allow data to be programmed in the storage 120 at a program (write) request of the host device. Furthermore, the controller 110 may provide the data written in the storage 120 to the host device in response to a read request of the host device. In an embodiment, the controller 110 may store a command transmitted from the host device in a command queue, and process the command according to a result obtained by scheduling a command processing order.

The storage 120 may write data or output the written data under the control of the controller 110. The storage 120 may include a volatile or nonvolatile memory apparatus. In an embodiment, the storage 120 may be implemented using a memory device selected from various nonvolatile memory devices such as an electrically erasable and programmable ROM (EEPROM), a NAND flash memory, a NOR flash memory, a phase-change RAM (PRAM), a resistive RAM (ReRAM), a ferroelectric RAM (FRAM), and a spin torque transfer magnetic RAM (STT-MRAM). The storage 120 may have a hierarchical structure having a page including a plurality of memory cells, a block including at least one page, a plane including at least one block, a die including at least one plane, and the like. Read and write (program) operations may be performed in units of pages for example, and an erase operation may be performed in units of blocks for example. In order to improve a data input/output speed, a processing unit of data to be read or written may be determined according to a manufacturing purpose and the like of the data storage device 10. The storage 120 may operate a single-level cell that stores one-bit data in one memory cell or a multi-level cell that stores multi-bit data in one memory cell.

The controller 110 may include a force garbage collection (FGC) controller 20.

The FGC controller 20 may hold the processing of a host command waiting in the command queue, and control force garbage collection to be performed when a block satisfying a predetermined condition is detected from the blocks constituting the storage 120. In an embodiment, a target block in the FGC operation may be a block satisfying the predetermined condition.

In an embodiment, the FGC controller 20 may use the number of times of reading per block as an FGC condition. In an embodiment, when power is supplied again after sudden power off (SPO) of the data storage device 10 and rebuilding is performed, the FGC controller 20 may use the presence or absence of an error of an open block as the FGC condition; however, an embodiment is not limited thereto.

After holding the host command queued in the command queue and performing the FGC, the FGC controller 20 may process the host command waiting in the command queue again.

FIG. 2 is a configuration diagram of the controller in accordance with an embodiment.

Referring to FIG. 2, the controller 110 in accordance with an embodiment may include a central processing unit (CPU) 111, a host interface (IF) 113, a ROM 1151, a RAM 1153, a memory interface (IF) 117, and the FGC controller 20.

The CPU 111 may be configured to transfer various types of control information required for a data read or write operation for the storage 120 to the host IF 113, the RAM 1153, and the memory IF 117. In an embodiment, the CPU 111 may operate according to firmware provided for various operations of the data storage device 10. In an embodiment, the CPU 111 may perform a function of a flash translation layer (FTL) for performing garbage collection, address mapping, wear leveling and the like for managing the storage 120, a function of detecting and correcting an error of data read from the storage 120, and the like.

The host IF 113 may provide a communication channel for receiving a command and a clock signal from the host device, and controlling data input/output under the control of the CPU 111. Particularly, the host IF 113 may provide a physical connection between the host device and the data storage device 10. The host IF 113 may provide interfacing with the data storage device 10 in correspondence with a bus format of the host device. The bus format of the host device may include at least one of standard interface protocols such as a secure digital, a universal serial bus (USB), a multi-media card (MMC), an embedded MMC (eMMC), a personal computer memory card international association (PCMCIA), a parallel advanced technology attachment (PATA), a serial advanced technology attachment (SATA), a small computer system interface (SCSI), a serial attached SCSI (SAS), a peripheral component interconnection (PCI), a PCI express (PCI-e or PCIe), and a universal flash storage (UFS).

The ROM 1151 may store program codes required for the operation of the controller 110, for example, firmware or software, and store code data and the like used by the program codes.

The RAM 1153 may store data required for the operation of the controller 110 or data generated by the controller 110.

In a booting operation, the CPU 111 may load a boot code stored in the storage 120 or the ROM 1151 to the RAM 1153, thereby controlling the booting operation of the data storage device 10.

The memory IF 117 may provide a communication channel for signal transmission/reception between the controller 110 and the storage 120. The memory IF 117 may write data, which has been temporarily stored in a buffer memory, in the storage 120 under the control of the CPU 111. Furthermore, the memory IF 117 may transfer data read from the storage 120 to the buffer memory for temporary storage.

The FGC controller 20 may control the FGC to be performed in preference to the host command on the basis of a predetermined FGC condition.

FIG. 3 is a configuration diagram of the FGC controller in accordance with an embodiment.

Referring to FIG. 3, the FGC controller 20 may include a determination circuit 201, a host command manager 203, and an FGC trigger 205.

The determination circuit 201 may determine whether the FGC is required, on the basis of the status of each block constituting the storage 120.

In an embodiment, the determination circuit 201 may determine whether the FGC is required, according to the number of times of reading per block or the detection of an open block in which an error has occurred during device rebuilding after the SPO; however, an embodiment is not limited thereto.

The host command manager 203 may hold the processing of a host command waiting in the command queue when the FGC is required as the determination result of the determination circuit 201. In an embodiment, when the FGC is completed, the host command manager 203 may resume the processing of the host command waiting in the command queue.

The FGC trigger 205 may enable an FGC processing signal when the host command waiting in the command queue is held under the control of the host command manager 203. Accordingly, the controller 110 may perform garbage collection by selecting a block satisfying the determination condition of the determination circuit 201 as a target block.

When the number of times of reading per block reaches a predetermined threshold value, the FGC processing signal is enabled and data of a block, in which the number of times of reading has reached the threshold value, is moved to another block (a sacrificial block), so that it is possible to prevent read disturbance failure. However, when the FGC for a specific block has been required but a command-queued host command is performed first, additional read stress may be added to a block to be subjected to the FGC processing. Therefore, since the accumulated number of times of reading increases before the FGC processing, the read disturbance failure may occur.

In the present technology, when a block requiring the FGC is detected, the processing of a queued host command is held and the FGC is performed first, so that it is possible to substantially prevent the read disturbance failure.

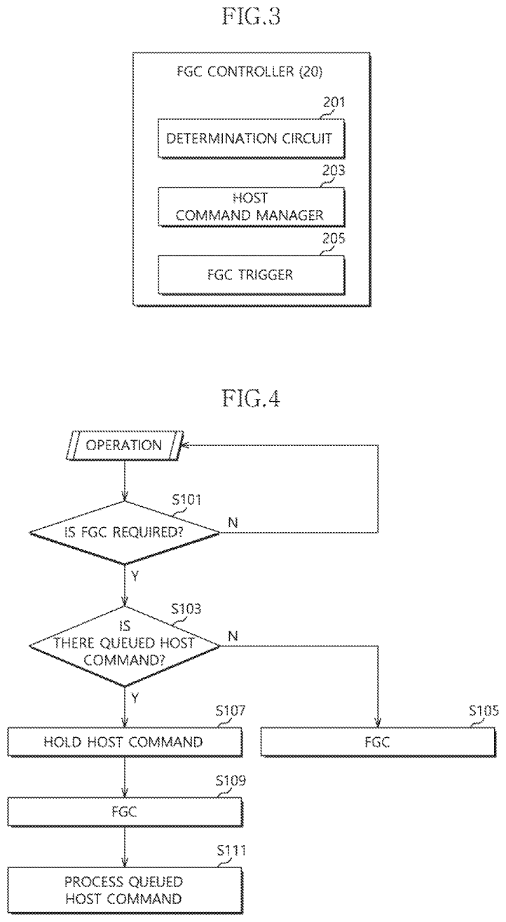

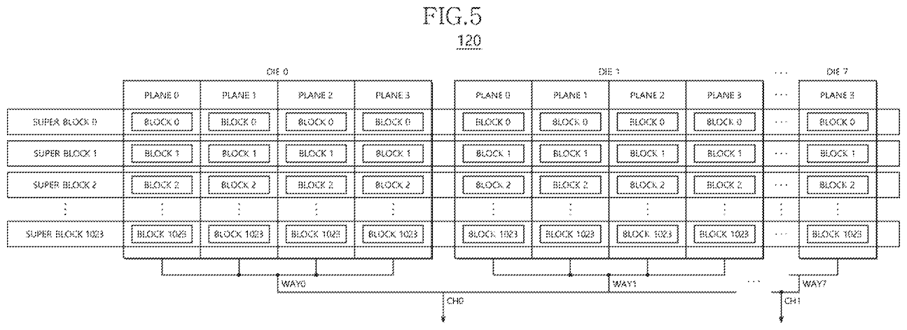

FIG. 4 is a flowchart describing an operation method of the data storage device in accordance with an embodiment.

The storage 120 may include a plurality of memory blocks, and the controller 110 may determine whether the FGC is required, on the basis of the status of each block constituting the storage 120 (S101).

In an embodiment, the memory blocks constituting the storage 120 may be managed in units of unit blocks or super blocks obtained by grouping a plurality of unit blocks.

FIG. 5 is a configuration diagram of the storage in accordance with an embodiment.

FIG. 5 illustrates that the storage 120 includes a plurality of memory dies DIE<0:7>, each of the plurality of memory dies DIE<0:7> includes a plurality of planes PLANE<0:3>, and each of the planes PLANE<0:3>*8 includes 1024 memory blocks BLOCK<0:1023>. In the storage 120, the plurality of planes PLANE<0:3>*8 included in the plurality of memory dies DIE<0:7> may input/output data through a plurality of channels CH<0:1> and a plurality of ways WAY<0:7>.

That is, in the storage 120 illustrated in FIG. 5, four ways WAY<0:3> or WAY<4:7> share one channel CH0 or CH1 and four planes PLANE<0:3> share one way WAY0, WAY1, WAY2, WAY3, WAY4, WAY5, WAY6, or WAY7.

The controller 110 may individually manage the plurality of memory blocks included in the storage 120 in units of super blocks. Referring to FIG. 5, the controller 110 may select an arbitrary one memory block from each of the planes PLANE<0:3>*8 included in the storage 120, and configure and manage one super block SUPER BLOCK <0:1023>. Accordingly, each of the super blocks SUPER BLOCK <0:1023> may include memory blocks corresponding to the number of planes.

Meanwhile, the controller 110 may simultaneously select 32 memory blocks included in each of the super blocks SUPER BLOCK <0:1023> during a data input/output operation, thereby counting the number of times of reading in units of super blocks SUPER BLOCK <0:1023> in the configuration in which the memory blocks are managed in units of super blocks as illustrated in FIG. 5.

In order to determine whether the FGC is required, on the basis of the status of each block or each super block constituting the storage 120, the controller 110 may determine whether the FGC is required, according to the number of times of reading per block (super block) or the detection of an open block (super block) in which an error has occurred during device rebuilding after the SPO; however, an embodiment is not limited thereto.

When it is determined that the FGC is required during the monitoring of whether the FGC is required (S101: Y), the controller 110 may confirm whether there is a host command waiting in the command queue (S103). When no host command is queued in the command queue, the controller 110 may immediately perform the FGC (S105).

FIG. 6 is a diagram describing command processing in accordance with an embodiment.

Referring to FIG. 6, the controller 110 may include a command queue 151 and a processor 111. The processor 111 may include one or more command execution circuits 153-1 to 153-n and a scheduler 155.

The command queue 151 may be configured to store a command transmitted from the host device. In an embodiment, the command queue 151 may store 32 commands.

The command execution circuits 153-1 to 153-n may be configured to process commands transferred from the command queue 151. Each of the command execution circuits 153-1 to 153-n may include a register that stores status information of each command being processed, for example, a command processing status. In an embodiment, the commands may be operated in a native command queuing (NCQ) manner and have unique tags expressed by numbers of 0 to 31.

The scheduler 155 may determine a processing order of commands stored in the command queue 151, and control the command execution circuits 153-1 to 153-n such that the commands are processed according to the determined order.

Accordingly, each of the command execution circuits 153-1 to 153-n may receive and execute the commands stored in the command queue 151 in response to the control of the scheduler 155, and manage the command processing status by a tag.

Referring back to FIG. 4, when it is confirmed in step S103 that there is the host command waiting in the command queue (S103: Y), the controller 110 may control the scheduler to hold the processing of the host command (S107). Then, the controller 110 may select a block determined to require the FGC in step S101 as a target block and perform the FGC (S109). That is, the controller 110 may move the data of the block determined to require the FGC to an empty block that is a sacrificial block.

When the FGC is completed, the controller 110 may control the scheduler to resume the processing of the host command waiting in the command queue (S111).

Consequently, it is possible to substantially prevent read stress from being added to the block determined to require the FGC.

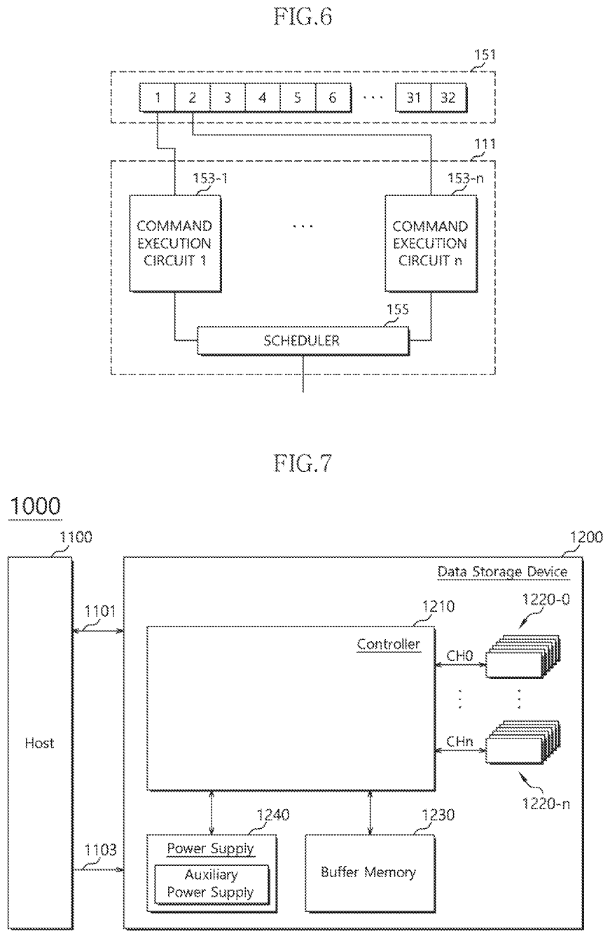

FIG. 7 is a diagram illustrating a data storage system in accordance with an embodiment.

Referring to FIG. 7, the data storage 1000 may include a host device 1100 and the data storage device 1200. In an embodiment, the data storage device 1200 may be configured as a solid state drive (SSD).

The data storage device 1200 may include a controller 1210, a plurality of nonvolatile memory devices 1220-0 to 1220-n, a buffer memory device 1230, a power supply 1240, a signal connector 1101, and a power connector 1103.

The controller 1210 may control general operations of the data storage device 1200. The controller 1210 may include a host interface, a control circuit, a random access memory used as a working memory, an error correction code (ECC), and a memory interface. In an embodiment, the controller 1210 may configured by controller 110 as shown is FIG. 1 to FIG. 3.

The host device 1100 may exchange a signal with the data storage device 1200 through the signal connector 1101. The signal may include a command, an address, data, and so forth.

The controller 1210 may analyze and process the signal received from the host device 1100. The controller 1210 may control operations of internal function blocks according to firmware or software for driving the data storage device 1200.

The buffer memory device 1230 may temporarily store data to be stored in at least one of the nonvolatile memory devices 1220-0 to 1220-n. Further, the buffer memory device 1230 may temporarily store the data read from at least one of the nonvolatile memory devices 1220-0 to 1220-n. The data temporarily stored in the buffer memory device 1230 may be transmitted to the host device 1100 or at least one of the nonvolatile memory devices 1220-0 to 1220-n according to control of the controller 1210.

The nonvolatile memory devices 1220-0 to 1220-n may be used as storage media of the data storage device 1200. The nonvolatile memory devices 1220-0 to 1220-n may be coupled with the controller 1210 through a plurality of channels CH1 to CHn, respectively. One or more nonvolatile memory devices may be coupled to one channel. The nonvolatile memory devices coupled to each channel may be coupled to the same signal bus and data bus.

The power supply 1240 may provide power inputted through the power connector 1103, to the inside of the data storage device 1200. The power supply 1240 may include an auxiliary power supply. The auxiliary power supply may supply power to allow the data storage device 1200 to be normally terminated when a sudden power-off occurs. The auxiliary power supply may include large capacity capacitors.

The signal connector 1101 may be configured by various types of connectors depending on an interface scheme between the host device 1100 and the data storage device 1200.

The power connector 1103 may be configured by various types of connectors depending on a power supply scheme of the host device 1100.

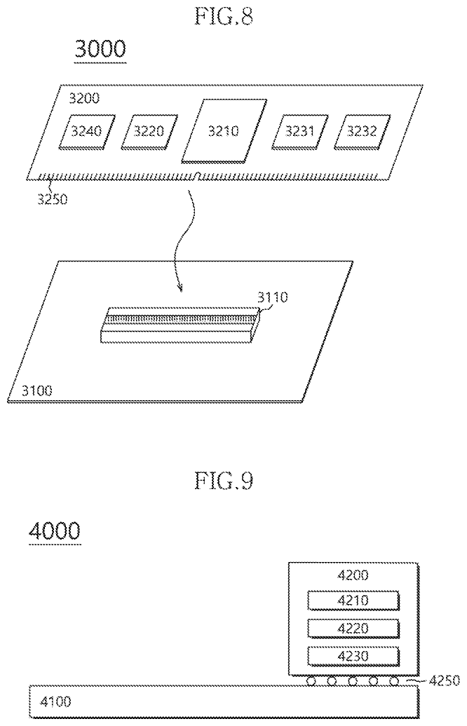

FIG. 8 is a diagram illustrating a data processing system in accordance with an embodiment. Referring to FIG. 8, the data processing system 3000 may include a host device 3100 and the memory system 3200.

The host device 3100 may be configured in the form of a board such as a printed circuit board. Although not shown, the host device 3100 may include internal function blocks for performing the function of a host device.

The host device 3100 may include a connection terminal 3110 such as a socket, a slot or a connector. The memory system 3200 may be mounted to the connection terminal 3110.

The memory system 3200 may be configured in the form of a board such as a printed circuit board. The memory system 3200 may be referred to as a memory module or a memory card. The memory system 3200 may include a controller 3210, a buffer memory device 3220, nonvolatile memory devices 3231 and 3232, a power management integrated circuit (PMIC) 3240, and a connection terminal 3250.

The controller 3210 may control general operations of the memory system 3200. The controller 3210 may be configured in the same manner as the controller 110 as shown in FIGS. 1 to 3.

The buffer memory device 3220 may temporarily store data to be stored in the nonvolatile memory devices 3231 and 3232. Further, the buffer memory device 3220 may temporarily store the data read from the nonvolatile memory devices 3231 and 3232. The data temporarily stored in the buffer memory device 3220 may be transmitted to the host device 3100 or the nonvolatile memory devices 3231 and 3232 according to control of the controller 3210.

The nonvolatile memory devices 3231 and 3232 may be used as storage media of the memory system 3200.

The PMIC 3240 may provide the power inputted through the connection terminal 3250, to the inside of the memory system 3200. The PMIC 3240 may manage the power of the memory system 3200 according to control of the controller 3210.

The connection terminal 3250 may be coupled to the connection terminal 3110 of the host device 3100. Through the connection terminal 3250, signals such as commands, addresses, data and so forth and power may be transferred between the host device 3100 and the memory system 3200. The connection terminal 3250 may be configured into various types depending on an interface scheme between the host device 3100 and the memory system 3200. The connection terminal 3250 may be disposed on any one side of the memory system 3200.

FIG. 9 is a diagram illustrating a data processing system in accordance with an embodiment. Referring to FIG. 9, the data processing system 4000 may include a host device 4100 and the memory system 4200.

The host device 4100 may be configured in the form of a board such as a printed circuit board. Although not shown, the host device 4100 may include internal function blocks for performing the function of a host device.

The memory system 4200 may be configured in the form of a surface-mounting type package. The memory system 4200 may be mounted to the host device 4100 through solder balls 4250. The memory system 4200 may include a controller 4210, a buffer memory device 4220, and a nonvolatile memory device 4230.

The controller 4210 may control general operations of the memory system 4200. The controller 4210 may be configured in the same manner as the controller 110 as shown in FIGS. 1 to 3.

The buffer memory device 4220 may temporarily store data to be stored in the nonvolatile memory device 4230. Further, the buffer memory device 4220 may temporarily store the data read from the nonvolatile memory device 4230. The data temporarily stored in the buffer memory device 4220 may be transmitted to the host device 4100 or the nonvolatile memory device 4230 according to control of the controller 4210.

The nonvolatile memory device 4230 may be used as the storage medium of the memory system 4200.

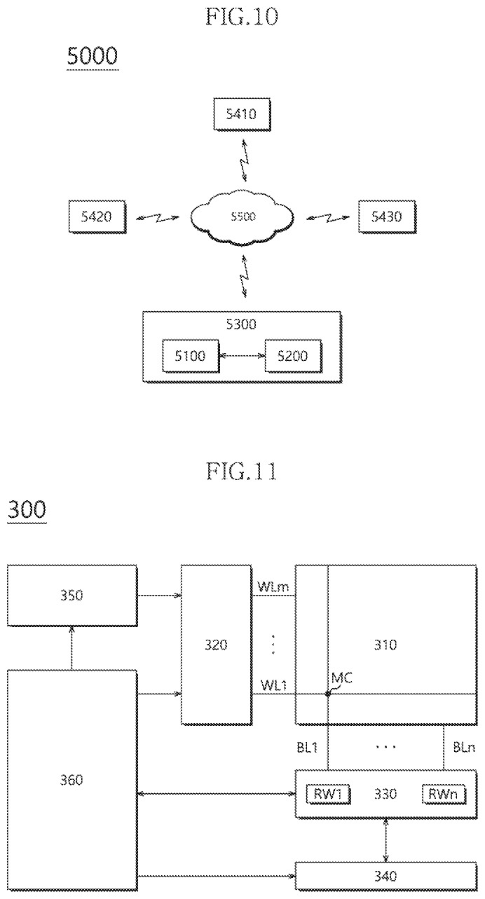

FIG. 10 is a diagram illustrating a network system including a data storage device in accordance with an embodiment. Referring to FIG. 10, the network system 5000 may include a server system 5300 and a plurality of client systems 5410 to 5430 which are coupled through a network 5500.

The server system 5300 may service data in response to requests from the plurality of client systems 5410 to 5430. For example, the server system 5300 may store the data provided from the plurality of client systems 5410 to 5430. For another example, the server system 5300 may provide data to the plurality of client systems 5410 to 5430.

The server system 5300 may include a host device 5100 and the memory system 5200. The memory system 5200 may be configured by the memory system 10 shown in FIG. 1, the data storage device 1200 shown in FIG. 7, the memory system 3200 shown in FIG. 8 or the memory system 4200 shown in FIG. 9.

FIG. 11 is a block diagram illustrating a nonvolatile memory device included in a data storage device in accordance with an embodiment. Referring to FIG. 11, the nonvolatile memory device 300 may include a memory cell array 310, a row decoder 320, a data read/write block 330, a column decoder 340, a voltage generator 350, and a control logic 360.

The memory cell array 310 may include memory cells MC which are arranged at areas where word lines WL1 to WLm and bit lines BL1 to BLn intersect with each other.

The memory cell array 310 may comprise a three-dimensional memory array. The three-dimensional memory array has a direction perpendicular to the flat surface of a semiconductor substrate. Moreover, the three-dimensional memory array means a structure including NAND strings in which at least one memory cell is located in a vertical upper portion of the other memory cell.

The structure of the three-dimensional memory array is not limited thereto. It is apparent that the memory array structure can be selectively applied to a memory array structure formed in a highly integrated manner with horizontal directionality as well as vertical directionality.

The row decoder 320 may be coupled with the memory cell array 310 through the word lines WL1 to WLm. The row decoder 320 may operate according to control of the control logic 360. The row decoder 320 may decode an address provided from an external device (not shown). The row decoder 320 may select and drive the word lines WL1 to WLm, based on a decoding result. For instance, the row decoder 320 may provide a word line voltage provided from the voltage generator 350, to the word lines WL1 to WLm.

The data read/write block 330 may be coupled with the memory cell array 310 through the bit lines BL1 to BLn. The data read/write block 330 may include read/write circuits RW1 to RWn respectively corresponding to the bit lines BL1 to BLn. The data read/write block 330 may operate according to control of the control logic 360. The data read/write block 330 may operate as a write driver or a sense amplifier according to an operation mode. For example, the data read/write block 330 may operate as a write driver which stores data provided from the external device, in the memory cell array 310 in a write operation. For another example, the data read/write block 330 may operate as a sense amplifier which reads out data from the memory cell array 310 in a read operation.

The column decoder 340 may operate according to control of the control logic 360. The column decoder 340 may decode an address provided from the external device. The column decoder 340 may couple the read/write circuits RW1 to RWn of the data read/write block 330 respectively corresponding to the bit lines BL1 to BLn with data input/output lines or data input/output buffers, based on a decoding result.

The voltage generator 350 may generate voltages to be used in internal operations of the nonvolatile memory device 300. The voltages generated by the voltage generator 350 may be applied to the memory cells of the memory cell array 310. For example, a program voltage generated in a program operation may be applied to a word line of memory cells for which the program operation is to be performed. For another example, an erase voltage generated in an erase operation may be applied to a well area of memory cells for which the erase operation is to be performed. For still another example, a read voltage generated in a read operation may be applied to a word line of memory cells for which the read operation is to be performed.

The control logic 360 may control general operations of the nonvolatile memory device 300, based on control signals provided from the external device. For example, the control logic 360 may control operations of the nonvolatile memory device 300 such as read, write and erase operations of the nonvolatile memory device 300. While various embodiments have been described above, it will be understood by those skilled in the art that the embodiments described are examples only. Accordingly, the data storage device, the operation method thereof, and the storage system including the same described herein should not be limited based on the described embodiments.

What is claimed is:

1. A data storage device comprising:
a storage configured to include a plurality of memory blocks; and
a controller configured to control data input/output to/from the storage,
wherein the controller comprises:
a command queue configured to queue a host command transmitted from a host device; and
a force garbage collection controller configured to control force garbage collection to be performed in preference to the queued host command when a block requiring the force garbage collection is detected from the plurality of memory blocks.

2. The data storage device according to claim 1, wherein the storage comprises a plurality of planes including the plurality of memory blocks and a plurality of dies including the plurality of planes.

3. The data storage device according to claim 2, wherein the controller is configured to control the storage in units of super blocks configured by selecting one memory block of the plurality of memory blocks from each of the plurality of planes.

4. The data storage device according to claim 1, wherein the force garbage collection controller comprises a determination circuit configured to detect the block requiring the force garbage collection from the plurality of memory blocks.

5. The data storage device according to claim 4, wherein the determination circuit is configured to detect the block requiring the force garbage collection, according to whether a number of times of reading per each of the plurality of memory blocks reaches a threshold value.

6. The data storage device according to claim 4, wherein the determination circuit is configured to detect the block requiring the force garbage collection, according to detection of an open block in which an error has occurred among the plurality of memory blocks during a rebuilding operation after sudden power off of the data storage device.

7. The data storage device according to claim 4, wherein the force garbage collection controller comprises a host command manager configured to control the command queue to stop processing the host command queued in the command queue when the block requiring the force garbage collection is detected by the determination circuit.

8. The data storage device according to claim 7, wherein the force garbage collection controller comprises a force garbage collection trigger configured to provide the controller with a signal for controlling the force garbage collection to be performed when the command queue is scheduled to stop the processing of the host command.

9. The data storage device according to claim 7, wherein the host command manager is configured to control the command queue in order to process the stopped host command when the force garbage collection is performed.

10. The data storage device according to claim 1, wherein the controller is configured to move data of the block detected as a block requiring the force garbage collection among the plurality of memory blocks to an empty block of the plurality of memory blocks during the force garbage collection operation.

11. A storage system comprising:
a host device;
a storage configured to include a plurality of memory blocks; and
a controller configured to control data input/output to/from the storage,
wherein the controller comprises:
a command queue configured to queue a host command transmitted from the host device; and
a force garbage collection controller configured to control force garbage collection to be performed in preference to the queued host command when a block requiring the force garbage collection is detected from the plurality of memory blocks.

12. The storage system according to claim 11, wherein the force garbage collection controller is configured to detect the block requiring the force garbage collection, according to whether a number of times of reading per each of the plurality of memory blocks reaches a threshold value.

13. The storage system according to claim 11, wherein the force garbage collection controller is configured to detect the block requiring the force garbage collection, according to detection of an open block in which an error has occurred among the plurality of memory blocks during a rebuilding operation after sudden power off of a data storage device.

14. The storage system according to claim 11, wherein the force garbage collection controller comprises a host command manager configured to control the command queue to stop processing the host command queued in the command queue when the block requiring the force garbage collection is detected.

15. The storage system according to claim 14, wherein the force garbage collection controller is configured to provide the controller with a signal for controlling the force garbage collection to be performed when the command queue is scheduled to stop the processing of the host command.

16. The storage system according to claim 14, wherein the force garbage collection controller is configured to control the command queue in order to process the stopped host command when the force garbage collection is performed.

17. The storage system according to claim 11, wherein the controller is configured to move data of the block detected as a block requiring the force garbage collection to an empty block of the plurality of memory blocks during the force garbage collection operation.

18. A memory system comprising:
a memory device including memory blocks; and
a controller configured to:
control the memory device to perform one or more operations in response to one or more queued commands, respectively; and
control the memory device to perform a force garbage collection operation to a target block among the memory blocks prior to processing the queued commands upon detection of the target block.
